(19) United States
(12) Patent Application Publication
(10) Pub. No.: US 2025/0133913 A1
(43) Pub. Date: Apr. 24, 2025

(54) DISPLAY DEVICE

(71) Applicant: Japan Display Inc., Tokyo (JP)

(72) Inventor: Sho YANAGISAWA, Tokyo (JP)

(73) Assignee: Japan Display Inc., Tokyo (JP)

(21) Appl. No.: 18/909,964

(22) Filed: Oct. 9, 2024

(30) Foreign Application Priority Data
Oct. 18, 2023 (JP) 2023-179396

(51) Int. Cl. H10K 59/122

(52) U.S. Cl. CPC H10K 59/122

(57) ABSTRACT

According to one embodiment, a display device includes a substrate having a display area and a surrounding area, an organic insulating layer formed of an organic insulating material, a rib layer which covers the organic insulating layer and has pixel apertures, and display elements overlapping the pixel apertures. The substrate has a first side. The organic insulating layer has a second side between the first side and the display area as seen in plan view, and a protrusion which protrudes from the second side toward the first side as seen in plan view and is provided at a position distant from an end portion of the second side. Further, the rib layer has a first slit overlapping the protrusion.

### CROSS-REFERENCE TO RELATED APPLICATION

This application is based upon and claims the benefit of priority from Japanese Patent Application No. 2023-179396, filed Oct. 18, 2023, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. In this type of display devices, a technique which can improve the yield is required.

### BRIEF DESCRIPTION OF THE DRAWINGS

FIG. 1 is a diagram showing a configuration example of a display device according to an embodiment.

FIG. 2 is a schematic plan view showing an example of the layout of subpixels.

FIG. 3 is a schematic cross-sectional view of the display device along the III-III line of FIG. 2.

FIG. 4 is a schematic plan view of the display device according to the embodiment.

FIG. 5 is a schematic enlarged plan view of the vicinity of the protrusion of the organic insulating layer shown in FIG. 4.

FIG. 6 is a schematic plan view of a substrate, the organic insulating layer and a slit near the protrusion.

FIG. 7 is a schematic cross-sectional view of the display device along the VII-VII line of FIG. 5.

FIG. 8 is a schematic enlarged plan view of the area VIII of FIG. 5.

FIG. 9 is a schematic plan view of a mother substrate according to the embodiment.

FIG. 10A is a schematic cross-sectional view showing the process of forming panel portions in the mother substrate.

FIG. 10B is a schematic cross-sectional view showing a process following FIG. 10A.

FIG. 10C is a schematic cross-sectional view showing a process following FIG. 10B.

FIG. 10D is a schematic cross-sectional view showing a process following FIG. 10C.

FIG. 10E is a schematic cross-sectional view showing a process following FIG. 10D.

FIG. 10F is a schematic cross-sectional view showing a process following FIG. 10E.

FIG. 10G is a schematic cross-sectional view showing a process following FIG. 10F.

FIG. 11 is a schematic plan view of the panel portion cut from the mother substrate.

FIG. 12 is a schematic enlarged plan view of the vicinity of the protrusion in the panel portion.

FIG. 13 is a schematic plan view of the substrate, the slit and the organic insulating layer in the panel portion.

FIG. 14 is a schematic cross-sectional view showing part of the panel portion in which a stacked film is formed by vapor deposition.

FIG. 15 is a diagram showing a comparative example of the embodiment.

### DETAILED DESCRIPTION

In general, according to one embodiment, a display device comprises a substrate having a display area which displays an image and a surrounding area around the display area, an organic insulating layer formed of an organic insulating material and provided above the substrate, a rib layer which is formed of an inorganic insulating material, covers the organic insulating layer and has a plurality of pixel apertures in the display area, and a plurality of display elements overlapping the pixel apertures, respectively. The substrate has a first side. The organic insulating layer has a second side located between the first side and the display area as seen in plan view, and a protrusion which protrudes from the second side toward the first side as seen in plan view and is provided at a position distant from an end portion of the second side. Further, the rib layer has a first slit overlapping the protrusion.

This configuration can improve the yield of the display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

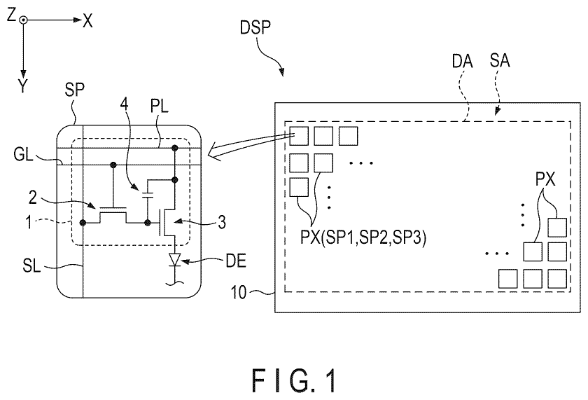

FIG. 1 is a diagram showing a configuration example of a display device DSP according to an embodiment. The display device DSP comprises an insulating substrate 10. The substrate 10 has a display area DA which displays an image, and a surrounding area SA around the display area DA. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in an X-direction and a Y-direction. Each pixel PX includes a plurality of subpixels SP which display different colors. This embodiment assumes a case where each pixel PX includes a blue subpixel SP1, a green subpixel SP2 and a red subpixel SP3. However, each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

A plurality of scanning lines GL which supply scanning signals to the pixel circuits 1 of subpixels SP, a plurality of signal lines SL which supply video signals to the pixel circuits 1 of subpixels SP and a plurality of power lines PL are provided in the display area DA. In the example of FIG. 1, the scanning lines GL and the power lines PL extend in the X-direction, and the signal lines SL extend in the Y-direction.

The gate electrode of the pixel switch 2 is connected to the scanning line GL. One of the source electrode and drain electrode of the pixel switch 2 is connected to the signal line SL. The other one is connected to the gate electrode of the drive transistor 3 and the capacitor 4. In the drive transistor 3, one of the source electrode and the drain electrode is connected to the power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

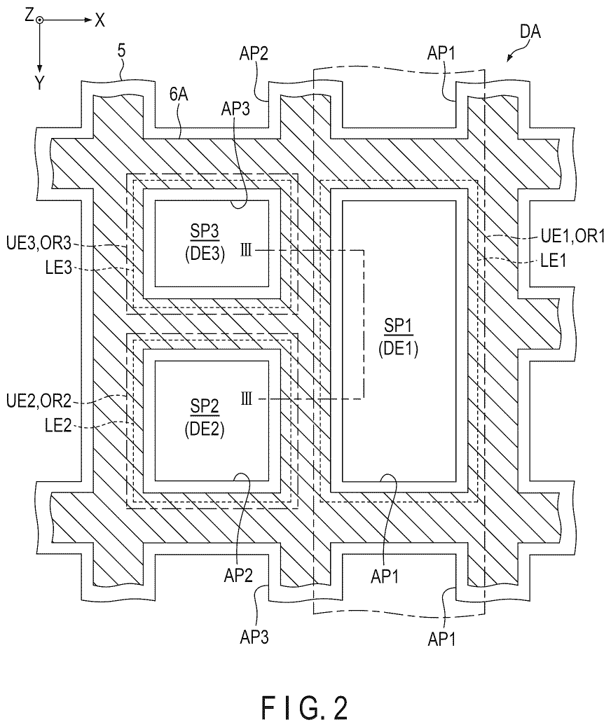

FIG. 2 is a schematic plan view showing an example of the layout of subpixels SP1, SP2 and SP3. In the example of FIG. 2, each of subpixels SP2 and SP3 is adjacent to subpixel SP1 in the X-direction. Further, subpixels SP2 and SP3 are arranged in the Y-direction.

When subpixels SP1, SP2 and SP3 are provided in line with this layout, a column in which subpixels SP2 and SP3 are alternately provided in the Y-direction and a column in which a plurality of subpixels SP1 are repeatedly provided in the Y-direction are formed in the display area DA. These columns are alternately arranged in the X-direction. It should be noted that the layout of subpixels SP1, SP2 and SP3 is not limited to the example of FIG. 2.

A rib layer 5 is provided in the display area DA. The rib layer 5 has pixel apertures AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3. Thus, among subpixels SP1, SP2 and SP3, the aperture ratio of subpixel SP1 is the greatest, and the aperture ratio of subpixel SP3 is the least.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib layer 5 surrounds each of these display elements DE1, DE2 and DE3.

A conductive partition (first partition) 6A is provided above the rib layer 5. The partition 6A overlaps the rib layer 5 as a whole and has a planar shape similar to that of the rib layer 5. In other words, the partition 6A has an aperture in each of subpixels SP1, SP2 and SP3. From another viewpoint, the rib layer 5 and the partition 6A have grating shapes as seen in plan view and surround each of the display elements DE1, DE2 and DE3. The partition 6A functions as lines which apply common voltage to the upper electrodes UE1, UE2 and UE3.

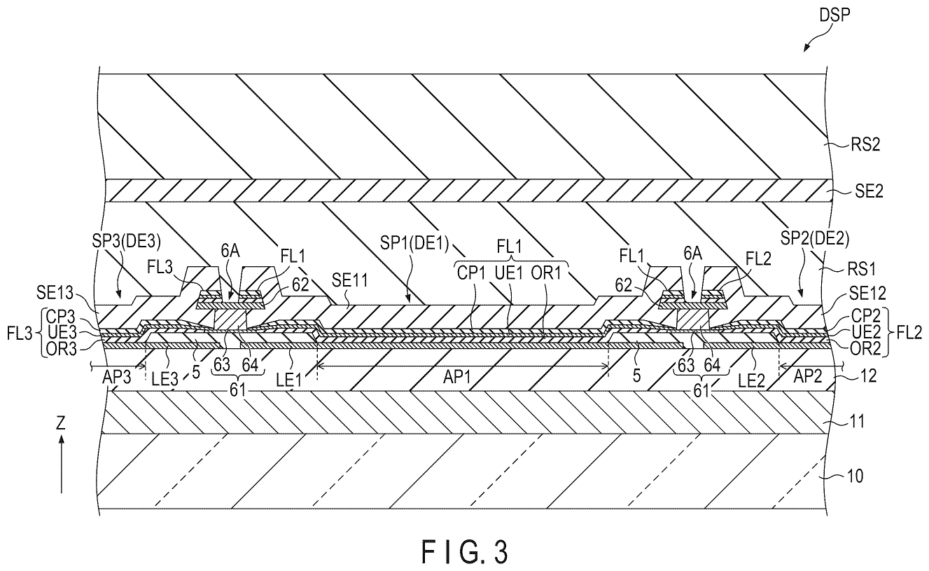

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuits 1, scanning lines GL, signal lines SL and power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib layer 5 is provided on the organic insulating layer 12 and the lower electrodes LE1, LE2 and LE3. The end portions of the lower electrodes LE1, LE2 and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6A includes a conductive lower portion 61 provided on the rib layer 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6A is called an overhang shape.

In the example of FIG. 3, the lower portion 61 has a bottom layer 63 provided on the rib layer 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the side surfaces of the lower portions 61 of the partition 6A.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The stacked film FL1 is partly located on the upper portion 62. This portion is spaced apart from, of the stacked film FL1, the portion located around the partition 6A (in other words, the portion which constitutes the display element DE1). Similarly, the stacked film FL2 is partly located on the upper portion 62. This portion is spaced apart from, of the stacked film FL2, the portion located around the partition 6A (in other words, the portion which constitutes the display element DE2). Further, the stacked film FL3 is partly located on the upper portion 62. This portion is spaced apart from, of the stacked film FL3, the portion located around the partition 6A (in other words, the portion which constitutes the display element DE3).

Sealing layers SE11, SE12 and SE13 are provided in subpixels SP1, SP2 and SP3, respectively. The sealing layer SE11 continuously covers the cap layer CP1 and the partition 6A around subpixel SP1. The sealing layer SE12 continuously covers the cap layer CP2 and the partition 6A around subpixel SP2. The sealing layer SE13 continuously covers the cap layer CP3 and the partition 6A around subpixel SP3.

In the example of FIG. 3, the stacked film FL1 and sealing layer SE11 located on the partition 6A between subpixels SP1 and SP2 are spaced apart from the stacked film FL2 and sealing layer SE12 located on this partition 6A. The stacked film FL1 and sealing layer SE11 located on the partition 6A between subpixels SP1 and SP3 are spaced apart from the stacked film FL3 and sealing layer SE13 located on this partition 6A.

The sealing layers SE11, SE12 and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a touch panel, a protective film or a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as polyimide. Each of the rib layer 5 and the sealing layers SE11, SE12, SE13 and SE2 is formed of an inorganic insulating material such as silicon nitride (SiNx), silicon oxide (SiOx), silicon oxynitride (SiON) or aluminum oxide (Al₂O₃). For example, the rib layer 5 is formed of silicon oxynitride, and each of the sealing layers SE11, SE12, SE13 and SE2 is formed of silicon nitride. Each of the resin layers RS1 and RS2 is formed of, for example, a resinous material (organic insulating material) such as epoxy resin or acrylic resin.

Each of the lower electrodes LE1, LE2 and LE3 has a reflective layer formed of, for example, silver, and a pair of conductive oxide layers covering the upper and lower surfaces of the reflective layer. Each of the conductive oxide layers may be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

Each of the organic layers OR1, OR2 and OR3 consists of a plurality of thin films including a light emitting layer. For example, each of the organic layers OR1, OR2 and OR3 comprises a structure in which a hole injection layer, a hole transport layer, an electron blocking layer, a light emitting layer, a hole blocking layer, an electron transport layer and an electron injection layer are stacked in order in a Z-direction. It should be noted that each of the organic layers OR1, OR2 and OR3 may comprise another structure such as a tandem structure including a plurality of light emitting layers.

Each of the cap layers CP1, CP2 and CP3 comprises, for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE11, SE12 and SE13. It should be noted that at least one of the cap layers CP1, CP2 and CP3 may be omitted.

Each of the bottom layer 63 and stem layer 64 of the partition 6A is formed of a metal material. For the metal material of the bottom layer 63, for example, molybdenum, titanium, titanium nitride (TiN), a molybdenum-tungsten alloy (MoW) or a molybdenum-niobium alloy (MoNb) can be used. For the metal material of the stem layer 64, for example, aluminum, an aluminum-neodymium alloy (AlNd), an aluminum-yttrium alloy (AlY) or an aluminum-silicon alloy (AlSi) can be used. It should be noted that the stem layer 64 may be formed of an insulating material.

For example, the upper portion 62 of the partition 6A comprises a multilayer structure consisting of a lower layer formed of a metal material and an upper layer formed of conductive oxide. For the metal material forming the lower layer, for example, titanium, titanium nitride, molybdenum, tungsten, a molybdenum-tungsten alloy or a molybdenum-niobium alloy can be used. For the conductive oxide forming the upper layer, for example, ITO or IZO can be used. It should be noted that the upper portion 62 may comprise a single-layer structure of a metal material. The upper portion 62 may further include a layer formed of an insulating material.

Common voltage is applied to the partition 6A. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively, based on the video signals of the signal lines SL.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

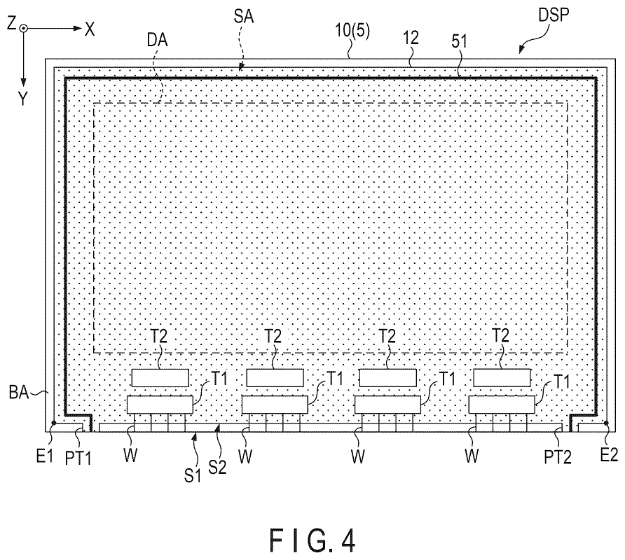

FIG. 4 is a schematic plan view of the display device DSP. In the figure, the dotted portions show the area in which the organic insulating layer 12 is provided. Thus, the organic insulating layer 12 is provided in the surrounding area SA as well as the display area DA.

The organic insulating layer 12 has an outer shape which is slightly smaller than the substrate 10. By this configuration, a margin area BA which does not overlap the organic insulating layer 12 is formed at the edge of the substrate 10.

The substrate 10 has a first side S1 (the lower side in the figure) extending in the X-direction. The organic insulating layer 12 has a second side S2 located between the first side S1 and the display area DA. The second side S2 is, for example, parallel to the first side S1.

The organic insulating layer 12 has a pair of protrusions PT1 and PT2 which protrude from the second side S2 toward the first side S1. The protrusion PT1 is located near an end portion E1 of the second side S2 (the left end portion in the figure). The protrusion PT2 is located near an end portion E2 of the second side S2 (the right end portion in the figure). In this embodiment, the protrusion PT1 is provided at a position distant from the end portion E1. The protrusion PT2 is provided at a position distant from the end portion E2.

The rib layer 5 shown in FIG. 2 and FIG. 3 is provided in the surrounding area SA as well as the display area DA. For example, the outer shape of the rib layer 5 is coincident with the outer shape of the substrate 10. The rib layer 5 has a slit (first slit) 51. The slit 51 overlaps the organic insulating layer 12 as a whole. The slit 51 is continuously formed along the outer shape of the organic insulating layer 12 and surrounds the display area DA excluding the second side S2 part. An end of the slit 51 overlaps the protrusion PT1. The other end of the slit 51 overlaps the protrusion PT2.

In the example of FIG. 4, four terminal portions T1 and four terminal portions T2 are provided in the surrounding area SA. All of these terminal portions T1 and T2 are located between the display area DA and the second side S2. The terminal portions T2 are located between the terminal portions T1 and the display area DA.

For example, a flexible printed circuit for supplying voltage and signals to the display device DSP is mounted on each terminal portion T1. For example, an IC chip (driver) for controlling image display is mounted on each terminal portion T2. These flexible printed circuits and IC chips are examples of electronic components.

A plurality of conductive lines W are further provided in the surrounding area SA. In the example of FIG. 4, four conductive lines W extend in the Y direction from each terminal portion T1. An end of each conductive line W is connected to the terminal portion T1, and the other end is located in the first side S1. Each conductive line W intersects with the second side S2 between the protrusions PT1 and PT2. As described in detail later, an inspection pad is connected to each conductive line W in the manufacturing process of the display device DSP.

It should be noted that the position of each terminal portion T1 or T2 or conductive line W or the number of terminal portions T1 or T2 or conductive lines W is not limited to the example shown in FIG. 4. Further, the display device DSP may not comprise the terminal portions T2. In this case, the above IC chips may be mounted in other places such as the flexible printed circuits.

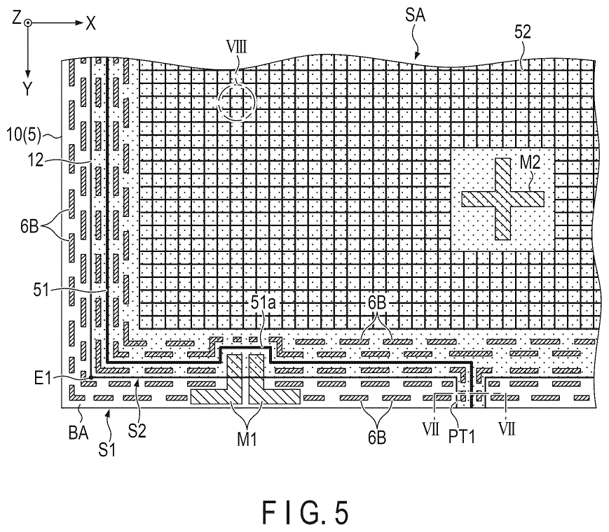

FIG. 5 is a schematic enlarged plan view of the vicinity of the protrusion PT1. The rib layer 5 further has a slit (second slit) 52 having a grating shape in the surrounding area SA. Moreover, a large number of partitions (second partitions) 6B are provided around the slit 52. For example, the slit 52 is located between each side of the organic insulating layer 12 including the second side S2 and the display area DA.

The partitions 6B are arranged at intervals along the outer shape of the substrate 10, the outer shape of the organic insulating layer 12 and the slit 51. For example, the partitions 6B are located in the area between the first side S1 and the second side S2, the area between the second side S2 and the slit 51 and the area between the slit 51 and the slit 52. In the example of FIG. 5, some of the partitions 6B overlap the protrusion PT1.

A pair of alignment marks M1 having an L-shape and a cruciform alignment mark M2 are provided near the protrusion PT1. The alignment marks M1 and M2 may be formed of, for example, the metal layer contained in the circuit layer 11 described above.

The pair of alignment marks M1 is located between the protrusion PT1 and the end portion E1 in the X-direction and overlaps the margin area BA and the second side S2. The slit 51 has a bent portion 51a which is bent along the alignment marks M1. By this configuration, the slit 51 does not overlap the alignment marks M1.

The alignment mark M2 is located in the area where the slit 52 is provided. In the example of FIG. 5, the grating of the slit 52 is open in a rectangular shape around the alignment mark M2. By this configuration, the slit 52 does not overlap the alignment mark M2.

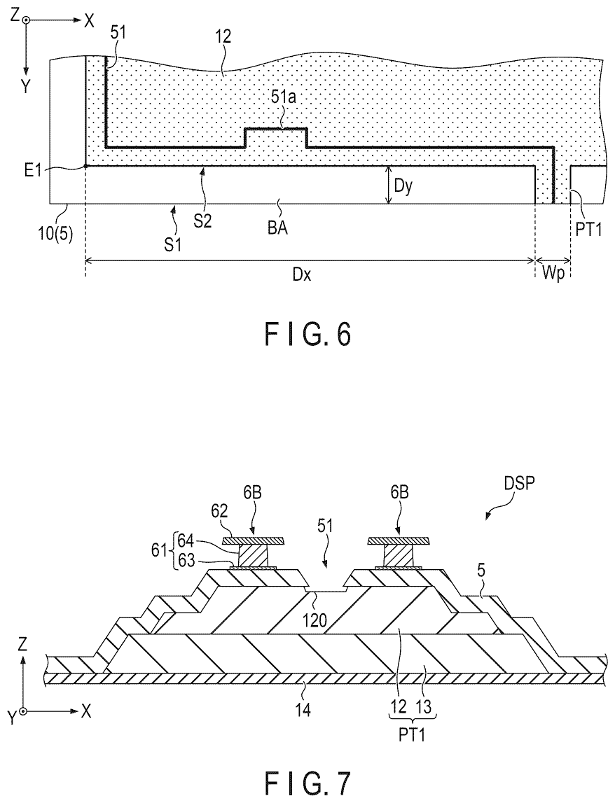

FIG. 6 is a schematic plan view of the substrate 10, the organic insulating layer 12 and the slit 51 near the protrusion PT1. In this figure, the partition 6B and the alignment marks M1 are omitted.

As described above, the protrusion PT1 is distant from the end portion E1 of the second side S2. Distance Dx between the end portion E1 and the protrusion PT1 in the X-direction is, for example, greater than or equal to 2 mm.

The first side S1 and the second side S2 are, for example, parallel to each other. Distance Dy between the first side S1 and the second side S2 in the Y-direction is less than distance Dx (Dy<Dx). Distance Dy is, for example, less than or equal to 0.2 mm. Width Wp of the protrusion PT1 in the X-direction is, for example, less than distance Dy (Wp<Dy).

A configuration similar to that of the vicinity of the protrusion PT1 shown in FIG. 5 and FIG. 6 can be applied to the vicinity of the protrusion PT2. For example, the distance between the protrusions PT1 and PT2 in the X-direction is greater than distance Dx.

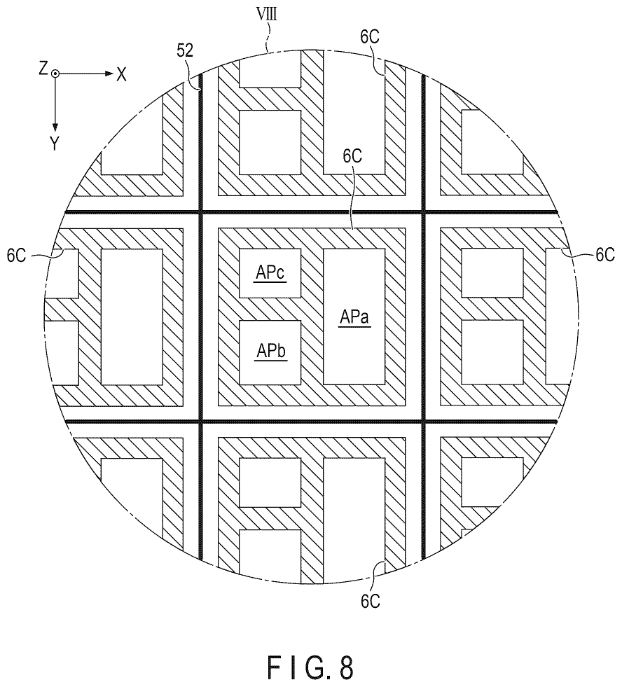

FIG. 7 is a schematic cross-sectional view of the display device DSP along the VII-VII line of FIG. 5. In this figure, the illustration of part of the substrate 10 and the circuit layer 11 is omitted. In the example of FIG. 7, an organic

insulating layer 13 is provided under the organic insulating layer 12. Further, an inorganic insulating layer 14 is provided under the organic insulating layer 13. These organic insulating layer 13 and inorganic insulating layer 14 are, for example, part of the circuit layer 11.

The organic insulating layer 13 is formed of an organic insulating material such as polyimide. The inorganic insulating layer 14 is formed of, for example, an inorganic insulating material such as silicon nitride, silicon oxide or silicon oxynitride.

In the example of FIG. 7, the width of the organic insulating layer 13 is greater than that of the organic insulating layer 12. The both end portions of the organic insulating layer 13 protrude relative to the both end portions of the organic insulating layer 12. The organic insulating layers 12 and 13 shown in FIG. 7 constitute the protrusion PT1. Similarly, the protrusion PT2 may consist of the organic insulating layers 12 and 13.

The rib layer 5 covers the organic insulating layers 12 and 13 and the inorganic insulating layer 14. In the section of FIG. 7, a pair of partitions 6B is provided above the protrusion PT1, and the slit 51 is provided between these partitions 6B.

The partitions 6B are formed by the same process as the partition 6A shown in FIG. 3 and have structures similar to the structure of the partition 6A. Specifically, each partition 6B has a lower portion 61 and an upper portion 62. Further, the lower portion 61 of each partition 6B has a bottom layer 63 and a stem layer 64.

The upper surface of the organic insulating layer 12 is exposed from the rib layer 5 through the slit 51. In the example of FIG. 7, the upper surface of the organic insulating layer 12 has a groove 120 which overlaps the slit 51. The groove 120 partly ranges on the lower side of the rib layer 5. By this configuration, the edge portion of the rib layer 5 along the slit 51 protrudes to the upper side of the groove 120. In other words, an overhang structure is formed by this edge portion and the groove 120.

In addition, the organic insulating layer 13 is provided on the lower side of substantially the entire part of the organic insulating layer 12 shown in FIG. 4 to FIG. 6. Thus, the slits 51 and 52 overlap the organic insulating layers 12 and 13 as seen in plan view. The groove 120 is formed so as to entirely overlap the slit 51 in addition to the position shown in the section of FIG. 7.

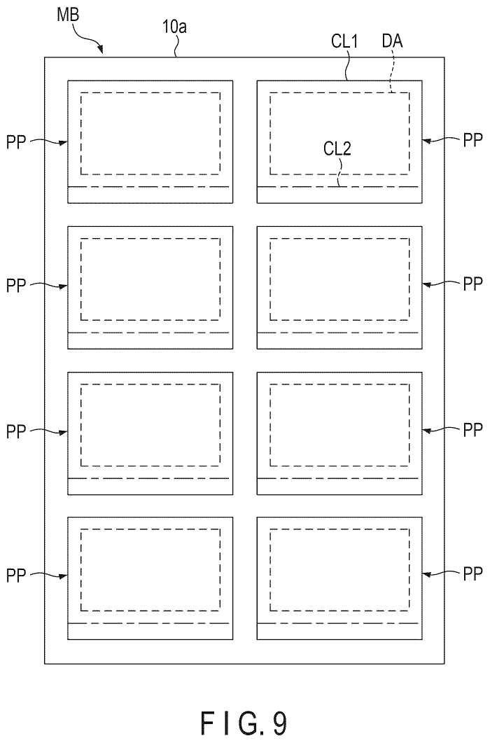

FIG. 8 is a schematic enlarged plan view of the area VIII of FIG. 5. A plurality of partitions (third partitions) 6C are provided in the respective areas surrounded by the slit 52 in the surrounding area SA.

For example, the partitions 6C are formed by the same process as the partitions 6A and 6B and have a structure similar to the structures of the partitions 6A and 6B. Specifically, each partition 6C has a lower portion 61 and an upper portion 62. Further, the lower portion 61 of each partition 6C has a bottom layer 63 and a stem layer 64.

In the example of FIG. 8, each partition 6C has three apertures APa, APb and APc. These apertures APa, APb and APc have shapes similar to those of the apertures surrounding subpixels SP1, SP2 and SP3 in the partition 6A shown in FIG. 2. Specifically, each of the apertures APb and APc is adjacent to the aperture APa in the X-direction, and further, the apertures APb and APc are arranged in the Y-direction. Further, the aperture APa is larger than the aperture APb, and the aperture APb is larger than the aperture APC.

It should be noted that each partition 6C may have apertures having shapes different from those of the apertures APa, APb and APc. The number of apertures provided in each partition 6C is not limited to three, and may be two or less, or four or greater.

The cross-sectional structure of the vicinity of the slit 52 is similar to that of the vicinity of the slit 51 shown in FIG. 7. Similarly, the groove 120 is present under the slit 52. Further, an overhang structure is formed by the edge portion of the slit 52 and the groove 120.

Now, this specification explains an example of the manufacturing method of the display device DSP. When the display device DSP is manufactured, a mother substrate in which a plurality of areas (panel portions) each corresponding to the display device DSP are formed is prepared.

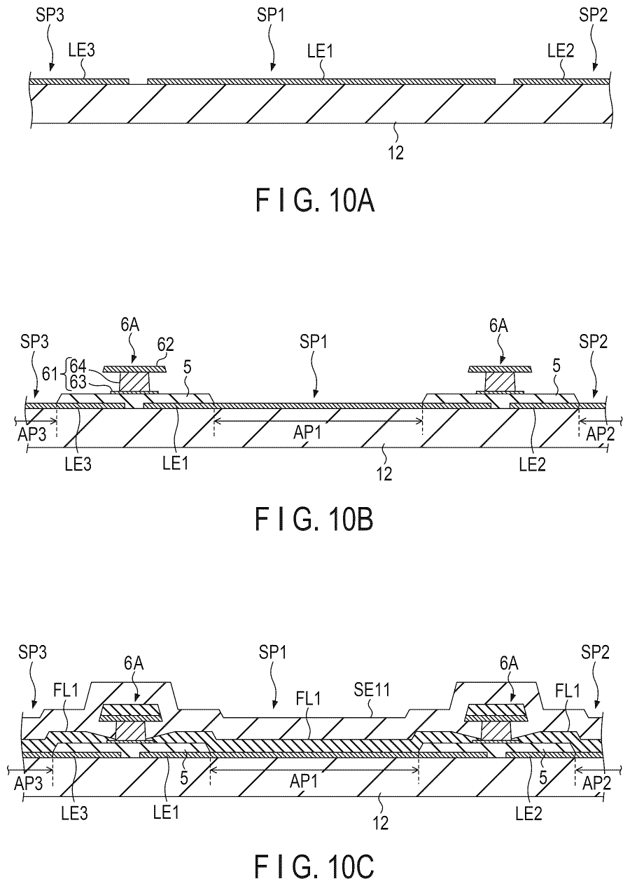

FIG. 9 is a schematic plan view of a mother substrate MB according to the embodiment. The mother substrate MB is, for example, rectangular as shown in the figure. However, the shape is not limited to this example.

The mother substrate MB has a large substrate 10a. The substrate 10a is formed of the same material as the substrate 10 described above. A plurality of panel portions PP provided in matrix are formed in the substrate 10a.

Each panel portion PP includes various elements provided in the display device DSP explained using FIG. 1 to FIG. 8, such as the display area DA. In the example of FIG. 9, the mother substrate MB has eight panel portions PP. However, the configuration is not limited to this example.

The outer shape of each panel portion PP corresponds to a cut line CL1 for cutting the panel portion PP out of the mother substrate MB. Further, each panel portion PP has a cut line CL2. The cut line CL2 corresponds to the first side S1 of the substrate 10 described above.

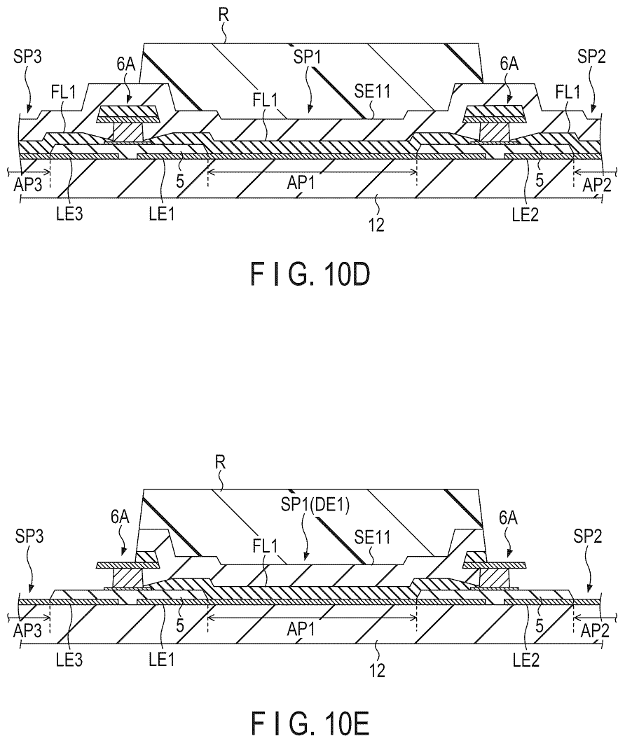

FIG. 10A to FIG. 10G are schematic cross-sectional views showing the process of forming the panel portions PP in the mother substrate MB. In FIG. 10A to FIG. 10G, the elements located on the lower side of the organic insulating layer 12 are omitted.

To form the panel portions PP, first, the substrate 10a shown in FIG. 9 is prepared, and the circuit layer 11 and the organic insulating layer 12 are formed on the substrate 10a. Subsequently, as shown in FIG. 10A, the lower electrodes LE1, LE2 and LE3 are formed on the organic insulating layer 12.

Subsequently, the rib layer 5 and the partition 6A are formed as shown in FIG. 10B. The pixel apertures AP1, AP2 and AP3 of the rib layer 5 may be provided after the formation of the partition 6A or may be provided before the formation of the partition 6A. For example, the slits 51 and 52 described above are formed together with the pixel apertures AP1, AP2 and AP3. Moreover, the partitions 6B and 6C are formed together with the partition 6A.

After the formation of the rib layer 5 and the partitions 6A, 6B and 6C, a process for forming the display elements DE1, DE2 and DE3 is performed. In the embodiment, this specification assumes a case where the display element DE1 is formed firstly, and the display element DE2 is formed secondly, and the display element DE3 is formed lastly. It should be noted that the formation order of the display elements DE1, DE2 and DE3 is not limited to this example.

To form the display element DE1, first, as shown in FIG. 10C, the stacked film FL1 and the sealing layer SE11 are formed. The stacked film FL1 includes, as shown in FIG. 3, the organic layer OR1 which is in contact with the lower electrode LE1 through the pixel aperture AP1, the upper electrode UE1 which covers the organic layer OR1 and the cap layer CP1 which covers the upper electrode UE1.

The organic layer OR1, the upper electrode UE1 and the cap layer CP1 are formed by vapor deposition. The sealing layer SE11 is formed by chemical vapor deposition (CVD).

The stacked film FL1 and the sealing layer SE11 are formed in the entire substrate 10a including the surrounding SA and the area between adjacent panel portions PP as well as the display area DA of each panel portion PP. The stacked film FL1 is divided into a plurality of portions by the partitions 6A, 6B and 6C having overhang shapes. The sealing layer SE11 continuously covers the portions into which the stacked film FL1 is divided, and the partitions 6A, 6B and 6C.

Subsequently, the stacked film FL1 and the sealing layer SE11 are patterned. In this patterning, as shown in FIG. 10D, a resist R is provided on the sealing layer SE11. The resist R covers subpixel SP1 and part of the partition 6A around the subpixel.

Subsequently, as shown in FIG. 10E, the portions of the stacked film FL1 and the sealing layer SE11 exposed from the resist R are removed by etching using the resist R as a mask. In other words, of the stacked film FL1 and the sealing layer SE11, the portions which overlap the lower electrode LE1 remain, and the other portions are removed. By this process, the display element DE1 is formed in subpixel SP1. For example, this etching includes wet etching and dry etching processes which are performed in order for the sealing layer SE11, the cap layer CP1, the upper electrode UE1 and the organic layer OR1. After these etching processes, the resist R is removed.

The display element DE2 is formed by a procedure similar to that of the display element DE1. Specifically, when the display element DE2 is formed, the stacked film FL2 and the sealing layer SE12 are formed in the entire substrate 10a. The stacked film FL2 includes, as shown in FIG. 3, the organic layer OR2 which is in contact with the lower electrode LE2 through the pixel aperture AP2, the upper electrode UE2 which covers the organic layer OR2 and the cap layer CP2 which covers the upper electrode UE2.

The organic layer OR2, the upper electrode UE2 and the cap layer CP2 are formed by vapor deposition. The sealing layer SE12 is formed by CVD. The stacked film FL2 is divided into a plurality of portions by the partitions 6A, 6B and 6C having overhang shapes. The sealing layer SE12 continuously covers the portions into which the stacked film FL2 is divided, and the partitions 6A, 6B and 6C. By patterning these stacked film FL2 and sealing layer SE12, the display element DE2 is formed in subpixel SP2 as shown in FIG. 10F.

The display element DE3 is formed by a procedure similar to the procedures of the display elements DE1 and DE2. Specifically, when the display element DE3 is formed, the stacked film FL3 and the sealing layer SE13 are formed in the entire substrate 10a. The stacked film FL3 includes, as shown in FIG. 3, the organic layer OR3 which is in contact with the lower electrode LE3 through the pixel aperture AP3, the upper electrode UE3 which covers the organic layer OR3 and the cap layer CP3 which covers the upper electrode UE3.

The organic layer OR3, the upper electrode UE3 and the cap layer CP3 are formed by vapor deposition. The sealing layer SE13 is formed by CVD. The stacked film FL3 is divided into a plurality of portions by the partitions 6A, 6B and 6C having overhang shapes. The sealing layer SE13 continuously covers the portions into which the stacked film FL3 is divided, and the partitions 6A, 6B and 6C. By patterning these stacked film FL3 and sealing layer SE13, the display element DE3 is formed in subpixel SP3 as shown in FIG. 10G.

After the display elements DE1, DE2 and DE3 are formed, the resin layer RS1, sealing layer SE2 and resin layer RS2 shown in FIG. 3 are formed in order. Further, each panel portion PP is cut from the mother substrate MB along the cut lines CL1.

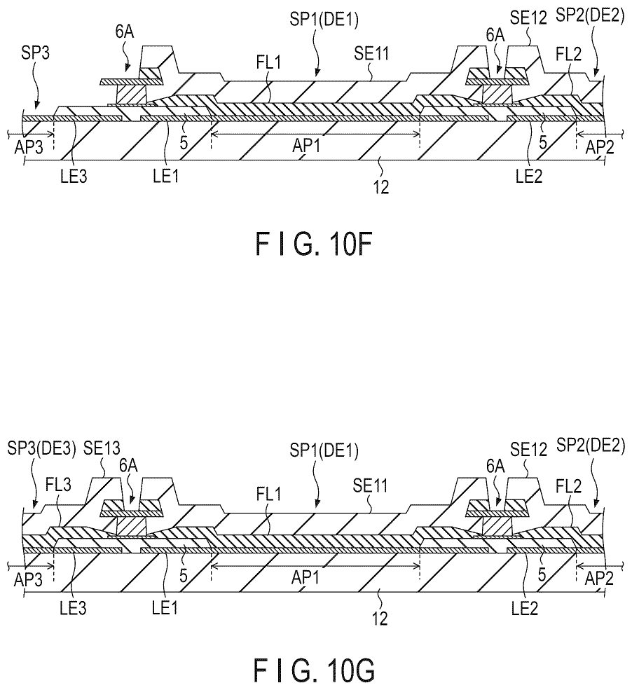

FIG. 11 is a schematic plan view of the panel portion PP cut from the mother substrate MB. The panel portion PP comprises a substrate 10b which is part of the substrate 10a described above. The substrate 10b has a body portion 101 and a pad portion 102. The border between the body portion 101 and the pad portion 102 is defined by the cut line CL2.

The body portion 101 includes the display area DA, surrounding area SA, terminal portions T1 and terminal portions T2 shown in FIG. 4. The pad portion 102 includes a plurality of inspection pads PD. The inspection pads PD are connected to the terminal portions T1 by the conductive lines W. Each conductive line W intersects with the cut line CL2.

The organic insulating layer 12 has a first part 121 formed in the body portion 101, and a second part 122 formed in the pad portion 102. The first part 121 and the second part 122 are spaced apart from each other via a gap along the cut line CL2 and are connected to each other by the protrusions PT1 and PT2.

The first part 121 and the second part 122 have outer shapes which are slightly smaller than the body portion 101 and the pad portion 102, respectively. By this configuration, a margin area BA which does not overlap the organic insulating layer 12 is formed at the edge of the substrate 10b.

The rib layer 5 described above is formed in, for example, the entire part of the body portion 101 and the pad portion 102. The slit 51 of the rib layer 5 is formed in the pad portion 102 in addition to the body portion 101.

In the example of FIG. 11, the slit 51 is formed along the outer shapes of the first and second parts 121 and 122 of the organic insulating layer 12 and overlaps the protrusions PT1 and PT2. In other words, the organic insulating layer 12 is entirely provided under the slit 51. For example, the organic insulating layer 13 is entirely provided under the organic insulating layer 12. The slit 51 surrounds the display area DA, the terminal portions T1, the terminal portions T2, the conductive lines W and the inspection pads PD.

The inspection pads PD are used for the inspection process of image display. In this inspection process, for example, probes for inspection are brought into contact with the inspection pads PD, and voltage is applied to the display elements DE1, DE2 and DE3 of the display area DA via the conductive lines W and the terminal portions T1.

After the inspection process, the panel portion PP is cut along the cut line CL2. At the time of this cutting, first, a scribe line is formed along the cut line CL2 by a scribing tool (for example, a scribing wheel). Further, the panel portion PP is cut along the scribe line. The body portion 101 from which the pad portion 102 has been separated corresponds to the display device DSP explained with reference to FIG. 1 to FIG. 8.

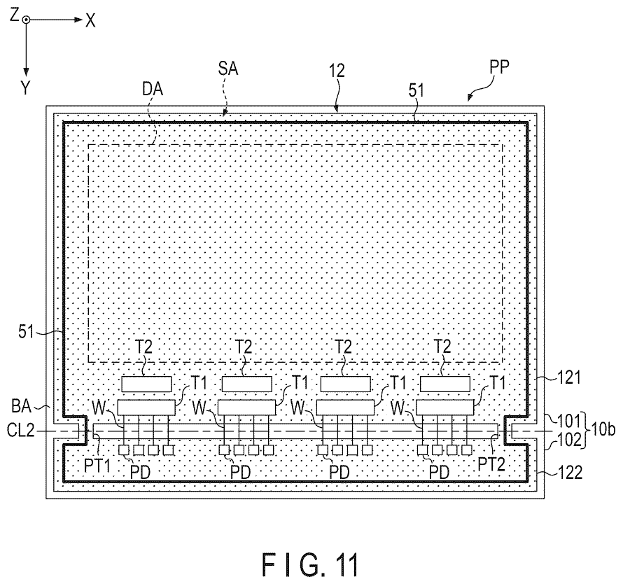

FIG. 12 is a schematic enlarged plan view of the vicinity of the protrusion PT1 in the panel portion PP. After the panel portion PP is cut, the first side S1 described above is formed along the cut line CL2.

The configuration of the body portion 101 near the cut line CL2 is similar to that of the display device DSP near the first side S1 shown in FIG. 5. The configuration of the pad portion 102 near the cut line CL2 is similar to that of the body portion 101 near the cut line CL2. Specifically, in a manner similar to that of the body portion 101, the pad portion 102 has a plurality of partitions 6B, a pair of alignment marks M1 and slits 51 and 52. Although not shown in FIG. 12, the partitions 6C shown in FIG. 8 are provided in the areas surrounded by the slit 52 in the pad portion 102.

In the example of FIG. 12, the body portion 101 and the pad portion 102 have a line-symmetric shape with respect to the cut line CL2 near the cut line CL2. The cut line CL2 passes through the area located between the pair of alignment marks M1 of the body portion 101 and the pair of alignment marks M1 of the pad portion 102. To form a satisfactory scribe line, it is preferable that the partitions 6B should not be provided at a position overlapping the cut line CL2.

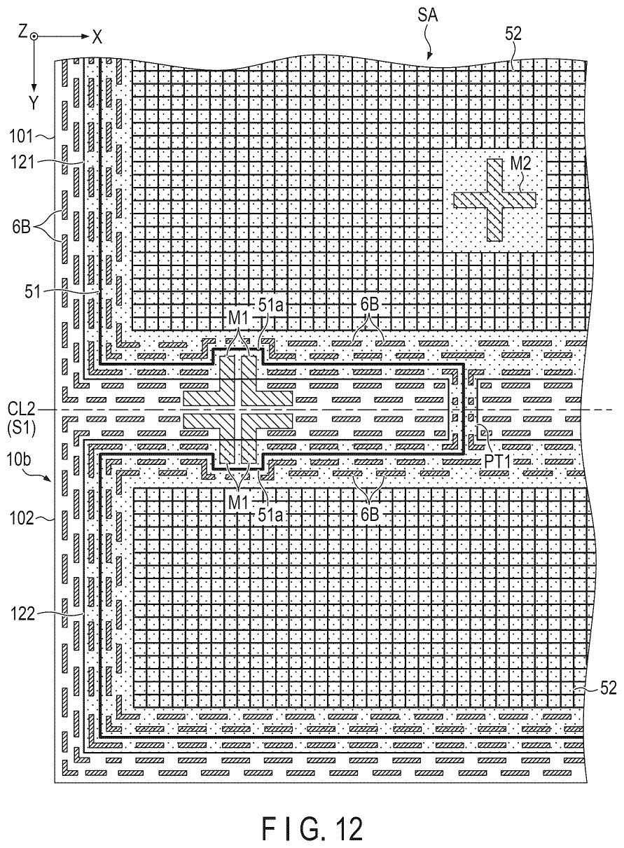

FIG. 13 is a schematic plan view of the substrate 10b, the slit 51 and the first and second parts 121 and 122 of the organic insulating layer 12 near the protrusion PT1. In this figure, the partitions 6B and the alignment marks M1 are omitted.

Scribing is applied in the scribing direction CD shown in the figure. Specifically, the scribing tool is firstly in contact with the starting point ST of the substrate 10b located near the protrusion PT1, passes through the area located between the first and second parts 121 and 122 of the organic insulating layer 12 and reaches the end point of the substrate 10b located near the protrusion PT2.

The four alignment marks M1 shown in FIG. 12 are used for the alignment of the scribing tool. In addition, the two alignment marks M1 of the body portion 101 can be used to check the misalignment of the cut position after the separation of the pad portion 102.

Now, this specification explains several effects obtained from the embodiment. When the display elements DE1, DE2 and DE3 are formed, the stacked films FL1, FL2 and FL3 are formed in the surrounding area SA and the pad portion 102 as well. The stacked films FL1, FL2 and FL3 which are formed by vapor deposition have weak adherence to the base. Therefore, there is a possibility that the stacked films FL1, FL2 and FL3 are peeled from the base during the manufacturing process of the display device DSP. When this peeling expands, the stacked films FL1, FL2 and FL3 and the sealing layers SE11, SE12 and SE13 located on these stacked films may be removed. Thus, they could be undesired particles.

In the display area DA, the stacked films FL1, FL2 and FL3 are divided into pieces by the partition 6A having a grating shape. Therefore, the stacked film FL1, FL2 or FL3 is not easily peeled from the base. Further, as explained below, in this embodiment, the peeling of the stacked films FL1, FL2 and FL3 in the surrounding area SA and the pad portion 102 is prevented by the partitions 6B and 6C and the slits 51 and 52.

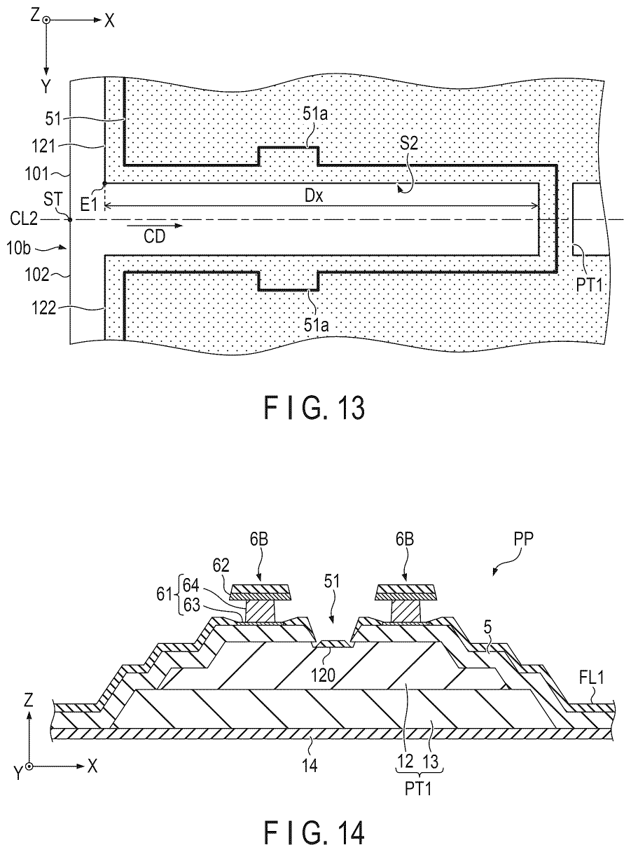

FIG. 14 is a schematic cross-sectional view showing part of the panel portion PP in which the stacked film FL1 is formed. The section shown as an example here cuts across the protrusion PT1 in a manner similar to that of FIG. 7.

The stacked film FL1 is divided by the partitions 6B having overhang shapes. Further, in this embodiment, an overhang structure is formed by the slit 51 of the rib layer 5 and the groove 120 of the organic insulating layer 12. Thus, the stacked film FL1 is divided in the slit 51 as well.

Although not shown in FIG. 14, the stacked film FL1 is similarly divided by the partitions 6C and the slit 52 as well. In this manner, in the embodiment, as the stacked film FL1 is divided in the surrounding area SA and the pad portion 102 as well, the stacked film FL1 is not easily peeled off. This effect is also applied to the stacked films FL2 and FL3.

The groove 120 can be formed by applying etching in which the etching rate for the organic insulating layer 12 is faster than the etching rate for the rib layer 5 after the formation of the slits 51 and 52. This etching may be etching for only forming the groove 12 or may be etching at the time of forming the partitions 6A, 6B and 6C.

When the slit 51 is formed along the outer shape of the panel portion PP as shown in FIG. 11, the stacked films FL1, FL2 and FL3 formed in the panel portion PP can be entirely separated from the stacked films FL1, FL2 and FL3 formed around the stacked films FL1, FL2 and FL3 formed in the panel portion PP. In addition, when a large number of partitions 6B and 6C are arranged at intervals as shown in FIG. 8 and FIG. 12, the expansion of the resist which is provided for patterning in the process after the formation of the partitions 6B and 6C is not easily blocked by the partitions 6B and 6C.

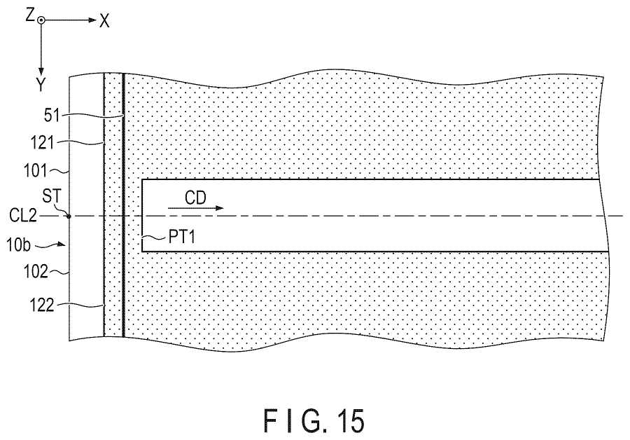

FIG. 15 is a diagram showing a comparative example of the embodiment and shows the schematic configuration of the vicinity of the protrusion PT1 in a manner similar to that of FIG. 13. In the comparative example, the protrusion PT1 connects the end portions of the first and second parts 121 and 122 of the organic insulating layer 12 in the X-direction to each other. In this configuration, the distance between the protrusion PT1 and the starting point ST is shorter than that of the example of FIG. 13.

At the time of the above scribing, the scribing tool cuts the protrusions PT1 and PT2. The scribing tool is in the middle of acceleration near the starting point ST. If the scribing tool hits against the protrusion PT1 in this state, the scribing tool wobbles, and thus, a satisfactory scribe line may not be formed.

To the contrary, in this embodiment, the protrusion PT1 is distant from the end portion E1 of the second side S2. This configuration can assure the acceleration distance to the position at which the scribing tool hits against the protrusion PT1, thereby preventing the wobble of the scribing tool. Thus, a satisfactory scribe line can be formed. When distance Dx between the end portion E1 of the second side S2 and the protrusion PT1 in the X-direction is, for example, greater than or equal to 2 mm as described above, the effect of preventing the wobble of the scribing tool can be sufficiently obtained.

As described above, according to the display device of the embodiment, the removal of the stacked films FL1, FL2 and FL3 can be prevented, and further, a satisfactory cutting along the cut line CL2 is possible. As a result, the yield of the display device DSP is improved. Various other desirable effects can be obtained from the present embodiment.

All of the display devices and manufacturing methods that can be implemented by a person of ordinary skill in the art through arbitrary design changes to the display device and manufacturing method thereof described above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a substrate having a display area which displays an image and a surrounding area around the display area;
an organic insulating layer formed of an organic insulating material and provided above the substrate;
a rib layer which is formed of an inorganic insulating material, covers the organic insulating layer and has a plurality of pixel apertures in the display area; and
a plurality of display elements overlapping the pixel apertures, respectively, wherein
the substrate has a first side,
the organic insulating layer has:
a second side located between the first side and the display area as seen in plan view; and
a protrusion which protrudes from the second side toward the first side as seen in plan view and is provided at a position distant from an end portion of the second side, and
the rib layer has a first slit overlapping the protrusion.

2. The display device of claim 1, wherein
the first slit surrounds the display area.

3. The display device of claim 1, wherein
the organic insulating layer has a groove overlapping the first slit.

4. The display device of claim 3, wherein
an edge portion of the rib layer along the first slit protrudes to an upper side of the groove.

5. The display device of claim 1, wherein
a distance between the end portion of the second side and the protrusion is greater than or equal to 2 mm.

6. The display device of claim 1, wherein
a width of the protrusion is less than a distance between the first side and the second side.

7. The display device of claim 1, wherein
each of the display elements includes:
a lower electrode;
an upper electrode located above the lower electrode; and
an organic layer which is located between the lower electrode and the upper electrode and emits light based on application of voltage.

8. The display device of claim 7, further comprising:
a first partition provided between the adjacent display elements in the display area; and
a plurality of second partitions provided around the first slit in the surrounding area, wherein
each of the first partition and the second partitions includes:
a conductive lower portion provided above the rib layer; and
an upper portion which has an end portion protruding from a side surface of the lower portion.

9. The display device of claim 8, wherein
the upper electrode is in contact with the lower portion of the first partition.

10. The display device of claim 8, wherein
each of the display elements further comprises an optical adjustment layer which covers the upper electrode.

11. The display device of claim 10, further comprising a sealing layer which is formed of an inorganic insulating material and continuously covers the optical adjustment layer and the first partition.

12. The display device of claim 8, wherein
at least one of the second partitions is located above the protrusion.

13. The display device of claim 1, wherein
the organic insulating layer has a pair of protrusions each identical with the protrusion, and
the first slit overlaps the pair of protrusions.

14. The display device of claim 13, further comprising a terminal portion which is located between the display area and the second side and on which an electronic component can be mounted.

15. The display device of claim 14, further comprising a conductive line which has an end connected to the terminal portion and the other end located in the first side, wherein
the conductive line intersects with the second side between the projections as seen in plan view.

16. The display device of claim 1, wherein
the rib layer further has a second slit located between the second side and the display area and having a grating shape.

17. The display device of claim 16, further comprising:
a first partition provided between the adjacent display elements in the display area; and
a third partition provided in an area surrounded by the second slit in the surrounding area, wherein
each of the first partition and the third partition includes:
a conductive lower portion provided above the rib layer; and
an upper portion which has an end portion protruding from a side surface of the lower portion.

18. The display device of claim 17, wherein
the third partition has an aperture.

19. The display device of claim 1, further comprising an alignment mark which overlaps the second side.

20. The display device of claim 19, wherein
the first slit is bent along the alignment mark.
